(19) United States
(12) Patent Application Publication
(10) Pub. No.: US 2020/0135464 A1
(43) Pub. Date: Apr. 30, 2020

(54) METHODS AND APPARATUS FOR PATTERNING SUBSTRATES USING ASYMMETRIC PHYSICAL VAPOR DEPOSITION

(71) Applicant: APPLIED MATERIALS, INC., SANTA CLARA, CA (US)

(72) Inventors: SREE RANGASAI V. KESAPRAGADA, UNION CITY, CA (US); JONATHAN R. BAKKE, SUNNYVALE, CA (US); JOUNG JOO LEE, SAN JOSE, CA (US); BENCHERKI MEBARKI, SANTA CLARA, CA (US); CHRISTOPHER NGAI, BURLINGAME, CA (US); REGINA FREED, LOS ALTOS, CA (US); GAURAV THAREJA, SANTA CLARA, CA (US); TEJINDER SINGH, SAN JOSE, CA (US); JORGE PABLO FERNANDEZ, SARATOGA, CA (US)

(21) Appl. No.: 16/175,289

(22) Filed: Oct. 30, 2018

(51) Int. Cl. H01L 21/033; C23C 14/34; C23C 14/58; C23C 14/04

(52) U.S. Cl. CPC H01L 21/0337; C23C 14/34; H01L 21/31122; C23C 14/04; H01L 21/0332; C23C 14/5873

(57) ABSTRACT

Methods and apparatus for processing a substrate are provided herein. In some embodiments, a method for processing a substrate includes: directing a stream of material from a PVD source toward a surface of a substrate at a non-perpendicular angle to the plane of the surface to selectively deposit the material on a top portion of one or more features on the substrate and form an overhang extending beyond a first sidewall of the one or more features; and etching a first layer of the substrate beneath the one or more features selective to the deposited material.

### FIELD

Embodiments of the present disclosure generally relate to substrate processing equipment, and more particularly, to methods and apparatus for performing physical vapor deposition (PVD).

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, to maintain satisfactory yields and reduce the cost of fabrication. Various technologies have been developed to deposit layers on substrates in a cost-effective and uniform manner, such as chemical vapor deposition (CVD) or physical vapor deposition (PVD).

However, the inventors have observed that with the drive to produce equipment to deposit more uniformly, certain applications may not be adequately served where purposeful deposition is required that is not symmetric or uniform with respect to the given structures being fabricated on a substrate. For example, the inventors have observed that asymmetric or non-uniform deposition of target material during a PVD process can advantageously be used to control the critical dimension of features formed on the underlying substrate.

### SUMMARY

Methods and apparatus for processing a substrate are provided herein. In some embodiments, a method for processing a substrate includes: directing a stream of material from a PVD source toward a surface of a substrate at a non-perpendicular angle to the plane of the surface to selectively deposit the material on a top portion of one or more features on the substrate and form an overhang extending beyond a first sidewall of the one or more features; and etching a first layer of the substrate beneath the one or more features selective to the deposited material.

In some embodiments, a method for processing a substrate includes: directing a stream of material from a PVD source toward a surface of a substrate at a non-perpendicular angle to the plane of the surface to selectively deposit the material on a top portion of one or more features on the substrate and form an overhang extending beyond a first sidewall of the one or more features; rotating the substrate; directing a stream of material from the PVD source toward a surface of a substrate at a different non-perpendicular angle to the plane of the surface to selectively deposit the material on the top portion of the one or more features on the substrate and form an overhang extending beyond at least one of a second sidewall and a third sidewall of the one or more features; and etching a first layer of the substrate beneath the one or more features selective to the deposited material.

In accordance with an aspect of the disclosure, there is provided a nontransitory computer readable storage medium having stored thereon a plurality of instructions that when executed cause a process controller to perform a method for processing a substrate. The method can include any of the embodiments disclosed herein. In some embodiments, the method includes: directing a stream of material from a PVD source toward a surface of a substrate at a non-perpendicular angle to the plane of the surface to selectively deposit the material on a top portion of one or more features on the substrate and form an overhang extending beyond a first sidewall of the one or more features; and etching a first layer of the substrate beneath the one or more features selective to the deposited material.

Other and further embodiments of the disclosure are described below.

### BRIEF DESCRIPTION OF THE DRAWINGS

Embodiments of the disclosure, briefly summarized above and discussed in greater detail below, can be understood by reference to the illustrative embodiments of the disclosure depicted in the appended drawings, in which:

FIG. 1 is a schematic diagram of a system that includes an apparatus used for PVD of material on substrates and an etching apparatus, in accordance with at least some embodiments of the disclosure;

FIG. 2 is a flowchart of a method for patterning a substrate, in accordance with at least some embodiments of the disclosure;

FIGS. 3A-3G illustrate schematic diagrams of stages of fabrication of a substrate undergoing methods in accordance with at least some embodiments of the disclosure;

FIGS. 4A-4C illustrate schematic diagrams of stages of fabrication of a substrate undergoing methods in accordance with at least some embodiment of the disclosure;

FIGS. 5A-5E illustrate schematic diagrams of stages of fabrication of a substrate undergoing methods in accordance with at least some embodiments of the disclosure;

FIGS. 6A-6B illustrate schematic diagrams of stages of fabrication of a substrate undergoing methods in accordance with at least some embodiments of the disclosure;

FIGS. 7A-7D illustrate schematic diagrams of stages of fabrication of a substrate undergoing methods in accordance with at least some embodiments of the disclosure;

FIGS. 8A-8E illustrate schematic diagrams of stages of fabrication of a substrate undergoing methods in accordance with at least some embodiments of the disclosure; and

FIGS. 9A-9B illustrate schematic diagrams of stages of fabrication of a substrate consistent with FIGS. 8A-8E in accordance with at least some embodiments of the disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods and apparatuses for controlling critical dimension of an underlying substrate are disclosed herein. Embodiments of the disclosed methods and apparatus advantageously enable uniform angular deposition of materials on a substrate. In such applications, deposited materials are asymmetric or angular with respect to a given feature on a substrate, but can be relatively uniform within all features across the substrate. Furthermore, embodiments of the disclosed methods and apparatus advantageously can be used for one or more of the formation of selective etch hard masks, line edge roughness control for etch hard mask, pattern critical dimension (CD) control, tip-to-tip reduction, and profile modulation.

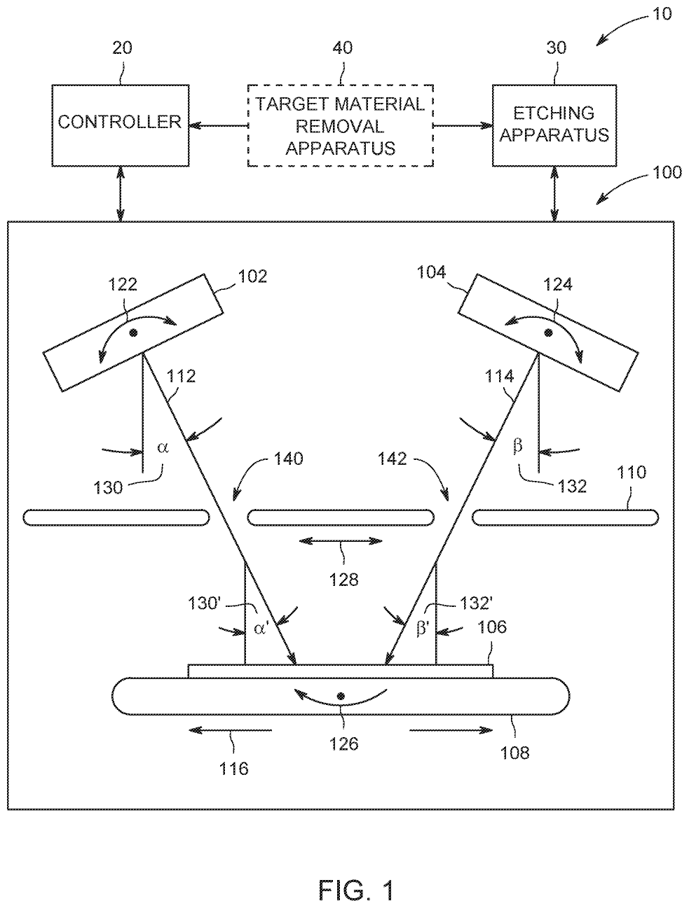

FIG. 1 is a schematic side view of a system 10 that includes a physical vapor deposition (PVD) apparatus 100, which can be controlled by a process controller (or processor) 20, and an etching apparatus 30, in accordance with at least some embodiments of the disclosure. In some embodiments, each of the PVD apparatus 100 and the etching apparatus 30 can be controlled by the process controller 20. In some embodiments, the etching apparatus 30 can be controlled by a separate controller.

The PVD apparatus 100 is configured for the deposition of materials on a substrate 106 at a non-perpendicular angle to the generally planar surface of the substrate. The PVD apparatus 100 generally includes a first PVD source 102 and a substrate support 108 for supporting a substrate 106. The PVD apparatus 100 can also include one or more collimators 110.

The first PVD source 102 is configured to provide a first directed stream of material flux (e.g., a first stream 112) from the source toward the substrate support 108 (and any substrate 106 disposed on the substrate support 108). In some embodiments, the PVD apparatus 100 may include a second PVD source 104 configured to provide a second directed stream of material flux (e.g., a second stream 114) from the source toward the substrate support 108 (and any substrate 106 disposed on the substrate support 108). The substrate support has a support surface to support the substrate such that a working surface of the substrate to be deposited on is exposed to the first stream 112 of material flux and, when present, the second stream 114 of material flux. The first and second streams 112, 114 of material flux provided by the first and second PVD sources 102, 104 have a width greater than that of the substrate support 108 (and any substrate 106 disposed on the substrate support 108). The first and second streams 112, 114 of material flux have a linear elongate axis corresponding to the width of the first and second streams 112, 114 of material flux. The substrate support 108 is configured to move linearly with respect to the first and second PVD sources 102, 104, as indicated by arrows 116. Optionally, the substrate support 108 may additionally be configured to rotate about a z-axis of the substrate support 108 (i.e., a central axis perpendicular to the support surface) or tilt about a y-axis of the substrate support 108, as indicated by arrow 126. Deposition of materials at a non-perpendicular angle to the substrate surface can be used to advantageously create an overhang that extends beyond one or more sidewalls of a feature that is disposed on the substrate 106, as will be described in greater detail below.

The first and second PVD sources 102, 104 include target material to be sputter deposited on the substrate. In some embodiments, the target material of the first and second PVD sources 102, 104 are the same target material. Alternatively, in some embodiments, the respective target materials of the first and second PVD sources 102, 104 are different from each other. The target material can be, for example, a metal, such as titanium, or the like, suitable for depositing titanium (Ti) or titanium nitride (TiN) on the substrate. In some embodiments, the target material can be, for example, silicon, or a silicon-containing compound, suitable for depositing silicon (Si), silicon nitride (SiN), silicon oxynitride (SiON), or the like on the substrate. Other suitable materials may be used as well in accordance with the teachings provided herein. The first PVD source 102 further includes, or is coupled to, a power source to provide suitable power for forming a plasma proximate the target material and for sputtering atoms off the target material. The power source can be either or both of a DC or an RF power source.

Unlike an ion beam or other ion source, the first and second PVD sources 102, 104 are configured to provide mostly neutrals and few ions of the target material. As such, a plasma may be formed having a sufficiently low density to avoid ionizing too many of the sputtered atoms of target material. For example, for a 300 mm diameter wafer as the substrate, about 1 to about 20 kW of DC or RF power may be provided. The power or power density applied can be scaled for other size substrates. In addition, other parameters may be controlled to assist in providing mostly neutrals in the first and second streams 112, 114 of material flux. For example, the pressure may be controlled to be sufficiently low so that the mean free path is longer than the general dimensions of an opening of the first and second PVD sources 102, 104 through which the stream of material flux passes toward the substrate support 108 (as discussed in more detail below). In some embodiments, the pressure may be controlled to be about 0.5 to about 5 millitorr.

The lateral angles of incidence of the first and second streams of material flux can be controlled. For example, FIG. 1 depicts the PVD apparatus 100 illustrating material deposition angle α 130 of the first stream 112 from the first PVD source 102 and angle β 132 of the second stream 114 from the second PVD source 104 in accordance with the present disclosure. The angles α 130 and β 132 can either be fixed or adjustable by rotating the first PVD source 102 as shown by arrow 122, and/or rotating the second PVD source 104 as shown by arrow 124. In some embodiments, the angles α 130 and β 132 can be measured as an average angle of incidence with respect to the plane of the substrate 106 (e.g., a simple average of maximum and minimum angles of incidence for particles in a given stream of material flux). In some embodiments, the angles α 130 and β 132 can be measured as a primary angle of incidence with respect to the plane of the substrate 106 (e.g., a volume or mass weighted average of various angles of incidence for particles in a given stream of material flux).

In addition to the angles α 130 and β 132, within-plane angles at which the first stream 112 and the second stream 114 are directed toward the substrate 106 surface can also be used to create the overhang on the feature that is disposed on a substrate, as discussed in more detail below.

As discussed above, the apparatus can optionally include the collimator 110. The collimator 110 is a physical structure such as a shroud, disk, a plurality of baffles, or the like, having one or more openings 140, 142. When present, the collimator 110 is interposed between the first and second PVD sources 102, 104 and the substrate 106 such that the first and second streams 112, 114 of material flux travel through the collimator 110 to reach the substrate 106. Any materials with an angle to great to pass through the openings 140, 142 of the collimator 110 will be blocked, thus limiting the permitted angular range of materials reaching the surface of substrate 106. The collimator 110 may include a single opening. Alternatively/additionally the PVD apparatus 100 may include a single collimator 110 having multiple openings. The collimator can function as a spread angle control apparatus that controls the angle of the spread of materials being sputtered from the first and/or second PVD sources. The one or more collimators 110 can move linearly as shown by arrow 128.

The angle of incidence 130′, 132′ at which the first and second streams 112, 114 of material actually contact the substrate surface may be different than the angle of incidence 130, 132 at which the streams of material are provide by the first PVD source 102 and the second PVD source 104. The angle of incidence 130′, 132′ at which the first and second streams 112, 114 of material actually contact the substrate surface can be controlled/altered by one or more of the following: the angle of incidence 130, 132 at which the streams of material are provided by the first PVD source 102 and the second PVD source 104, the number and placement of openings in collimator 110, the linear position of collimator 110, and the rotation (e.g. arrow 126) of the substrate support 108 about the x-axis, y-axis, and/or z-axis.

The process controller 20 controls the overall operation of the PVD chamber 11. More particularly, the process controller 20 controls at least one or more of the first PVD source 102, the second PVD source 104 (when present), the substrate support 108, or the collimator 110 (when present). The process controller 20 can control movement of the substrate support 108, movement of the first PVD source 102 and movement of the second PVD source 104 for directing the first and second streams 112, 114 of material flux toward the substrate at one or more of the above-reference angles, and movement of the collimator 110, if used. The process controller 20 can also control a pressure inside the PVD apparatus 100 and an amount of power provided to a target material prior to, during and/or after PVD of the material onto the substrate 106.

The etching apparatus 30 can be configured to perform one or more suitable etching processes. For example, the etching apparatus 30 can be configured to perform a dry etching process and/or a wet etching process. The etching apparatus 30, for example, can be configured to perform a dry plasma etching process suitable for selectively etching materials as described in more detail below.

After an etching process of the substrate 106 is completed, removal of the deposited material may be necessary. Accordingly, one or more suitable target material removal apparatus 40 may be used to remove (e.g., strip away) the deposited material from the substrate 106. For example, the target material removal apparatus 40 can be a plasma etch chamber, which can be a component of the etching apparatus 30, but configured to etch material deposited on the substrate 106 using one or more gases that can be different from the gases used by the etching apparatus 30, or a separate stand-alone apparatus that can, for example, use dry O₂ ashing or other suitable techniques to remove/strip the deposited material from the substrate 106.

The methods and embodiments disclosed herein advantageously enable deposition of materials with a shaped profile (e.g., creating an overhang) that may advantageously be used as an etch mask layer to control the shape of an underlying pattern to be etched into one or more layers of the substrate.

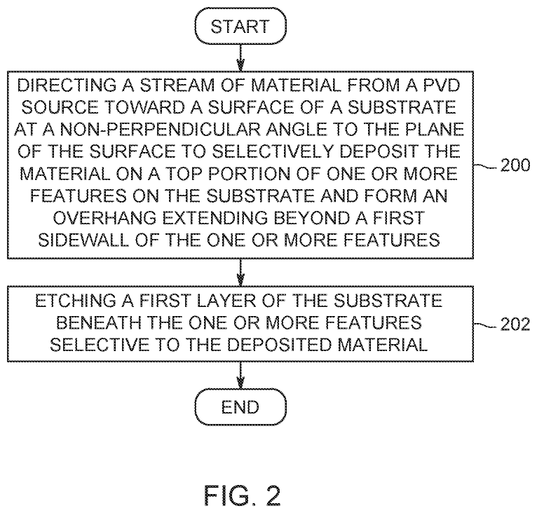

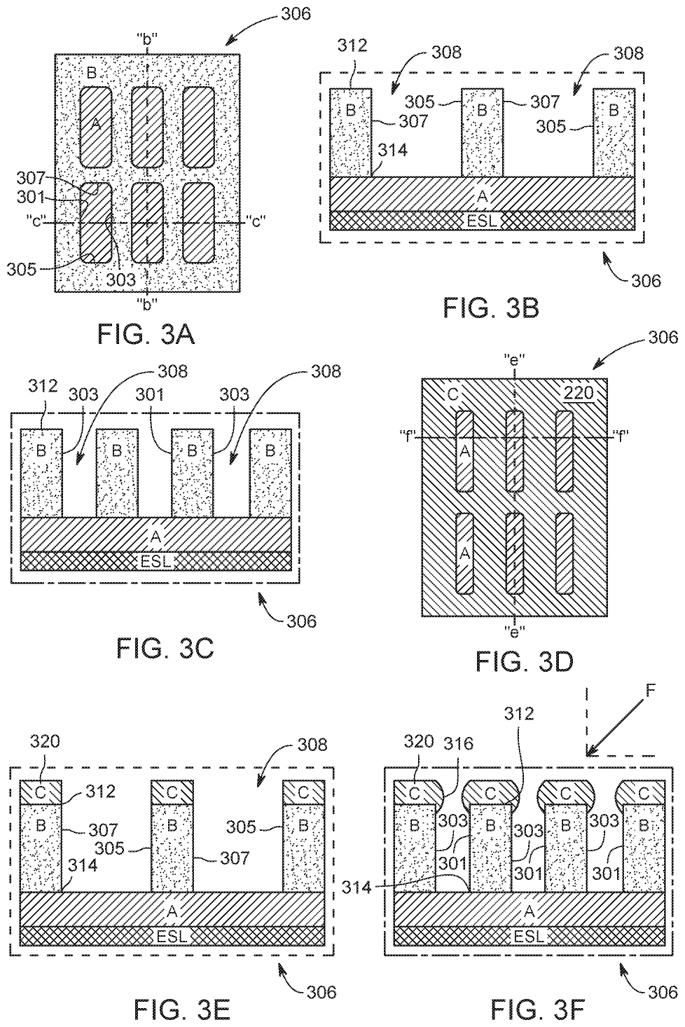

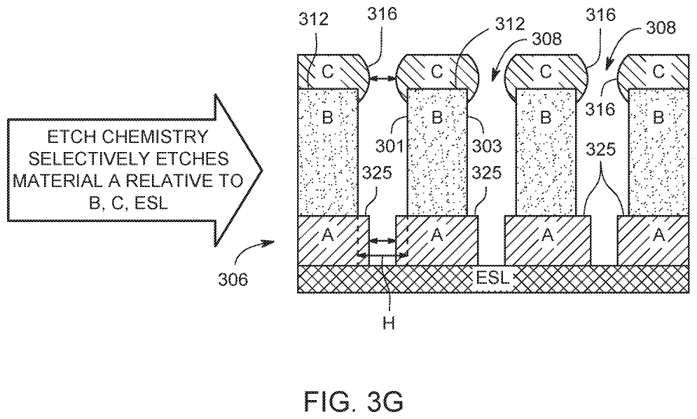

For example, FIG. 2 depicts a flowchart of a method for patterning a substrate 306 in accordance with at least some embodiments of the disclosure. The method of FIG. 2 can be used, for example, to control one or more critical dimensions of features formed in or on one or more layers of the substrate. FIGS. 3A-3G illustrate schematic diagrams of the stages of fabrication of the substrate 306 in accordance with at least some embodiments of the disclosure.

FIG. 3A, is a top plan view illustrating the substrate 306, which includes an etch stop layer (ESL, see FIG. 3B, for example) having disposed thereon a first layer A (layer A) and a second layer B (layer B) including at least one feature 308 (a plurality of features 308 are shown) disposed over layer A. Examples of material that can used for the ESL can include, but is not limited to, aluminum nitride (AlN), aluminum oxynitride (AlON), titanium nitride (TiN), silicon oxycarbide (SiOC), silicon oxynitride (SiON), etc. Examples of material that can used for the layer A can include, but is not limited to, silicon nitride (SiN), titanium nitride (TiN), silicon oxide (SiOₓ), etc. Examples of material that can used for the layer B can include, but is not limited to, spin-on carbon (SOC), advanced patterning film (APF), amorphous carbon (α-C), photo resistive film (PR), silicon (Si), etc. The features 308 can be a fin, trench, a via, or dual damascene feature, or the like, and can protrude from the substrate 306 rather than extend into the layer A of the substrate 306. FIGS. 3B and 3C are cross-sectional views taken along line segment “b-b,” and “c-c,” respectively. The cross-sectional views of FIGS. 3B and 3C illustrate the layer B as single or independent pillars or columns.

FIG. 3D is a top plan view illustrating the substrate 306 having a material 320 deposited on the layer B via the PVD processes described above, and FIGS. 3E and 3F are cross-sectional views taken along line segments “e-e”, and “f-f,” respectively, and also illustrate the layer B as single or independent pillars or columns, but with the material 320 having been deposited thereon. Examples of the material 320 that can be deposited on the substrate 306 (e.g., atop the layer A, layer B, and/or the ESL) can include, but is not limited to, titanium (Ti), titanium nitride (TiN), silicon (Si), silicon nitride (SiN), carbon (C), and silicon oxynitride (SiON).

The layer B includes a top portion 312, on which the material 320 is deposited, and a bottom portion 314 that extends from the layer A (FIGS. 3B and 3E). The features 308 (e.g., vias, trenches, or the like) extend through the layer B and are defined by first and second sidewalls 301, 303 (FIGS. 3C and 3F), and third and fourth sidewalls 305, 307 (FIGS. 3B and 3E). In some embodiments, the first and second sidewalls 301, 303 and the third and fourth sidewalls 305, 307 can be parallel and opposite to each other, while the first and second sidewalls 301, 303 and the third and fourth sidewalls 305, 307 can arranged at a non-zero angle to each other, and in the example shown at 90 degrees (adjacent) to each other.

The method for controlling critical dimension of the substrate 306, begins at 200 where a stream of material 320 from the first PVD source 102 is directed towards the substrate 306 surface at a non-perpendicular angle, e.g., a 130, a 132, or other suitable angle (see directional arrow F of FIG. 3F, for example), to the plane of the substrate 306 surface. Alternatively/additionally, the second PVD source 104 or both the first and second PVD sources 102, 104, respectively can be used to deposit the material 320.

The material 320 is deposited on the top portion 312 of the layer B to form an overhang 316 that extends beyond the first and second sidewalls 301, 303 that define the feature 308. More particularly, the stream of material 320 is directed from the first PVD source 102, and the angle at which the stream of material 320 is directed allows for asymmetric deposition of the material 320 around the features 308. That is, the overhang 316 only extends beyond the first and second sidewalls 301, 303, but does not extend, or does not substantially extend, beyond the third and fourth sidewalls 305, 307 (compare FIGS. 3C and 3F, for example) because of the angle of the stream of the material 220. Alternatively or in combination, in some embodiments, overhang may be formed on the third and fourth sidewalls by control of the relative orientation of the substrate with respect to the stream of material. A small amount of material 320 can be deposited on a relatively small area of the first and second sidewalls 301, 303 adjacent the top portion 312 of the layer B and can support the overhang 316. The stream of material 320 can also be directed from the first PVD source 102 at angle that provides deposition of the material 320 on the layer A of substrate 306, as will be described in greater detail below.

The collimator 110, which includes an opening, can be used to limit the angular range of the stream of material 320. More particularly, the placement of the collimator 110 (and physical structure of the collimator 110) with respect to the first PVD source 102 can be used to control the angle of incidence 130′ that the stream of the material 320 contacts the surface of the substrate 306, and, therefore can be used to control how far the overhang 316 extends beyond the first and second sidewalls 301, 303; however, as noted above, use of the collimator 110 is optional.

The substrate 306 can be scanned (e.g., linearly along arrow 116) through the stream of material 320 via the substrate support 108 to ensure that the material 320 forms an overhang 316 that extends beyond only the first and second sidewalls 301, 303 that define features 308, with minimal or no coverage on the first and second sidewalls 301, 303.

The amount/distance that the overhang 316 extends beyond the first and second sidewalls 301, 303 can depend on, but is not limited to, the material used for the PVD process, the angle at which the stream of material 320 is provided at, the angle of incidence 130′ that is controlled by the collimator 110, how many times the substrate support 108 is scanned, an angle at which the substrate support 108 is rotated, whether or not the second PVD source 104 is used in conjunction with the first PVD source 102, etc.

At 202, the substrate 306 is selectively etched using the etching apparatus 30, which as noted above, can be configured to perform a dry etching process, or other suitable etching process on the substrate 306. More particularly, and with reference to FIG. 3G, the substrate 306 is etched such that layer A is etched relative to layer B, the ESL, and the overhang 316 based on how far out the overhang 316 extends beyond the first and second sidewalls 301, 303. The etch process can be an anisotropic, or directional etch in a substantially orthogonal direction to the substrate. That is, the portions 325 of the layer A that are covered by the overhang 316 are not etched (or not substantially etched) during the etching process, which results in the layer A of the substrate 306 being etched less than the layer A would have been etched if the portion 325 of the layer A was not covered by the overhang 316 (see area defined by arrow H of FIG. 3G, for example). The etch process thus extends the pattern defined by the plurality of features 308 into the layer A, while controlling the critical dimension (e.g., the width of the feature) of the feature by control of the overhang 316, which acts as a masking layer for the etch process. The etch process can be performed for a suitable duration until, for example, the ESL is reached.

While the above method has been described herein as including the first and second sidewalls 301, 303 with the overhang 316, the disclosure is not so limited.

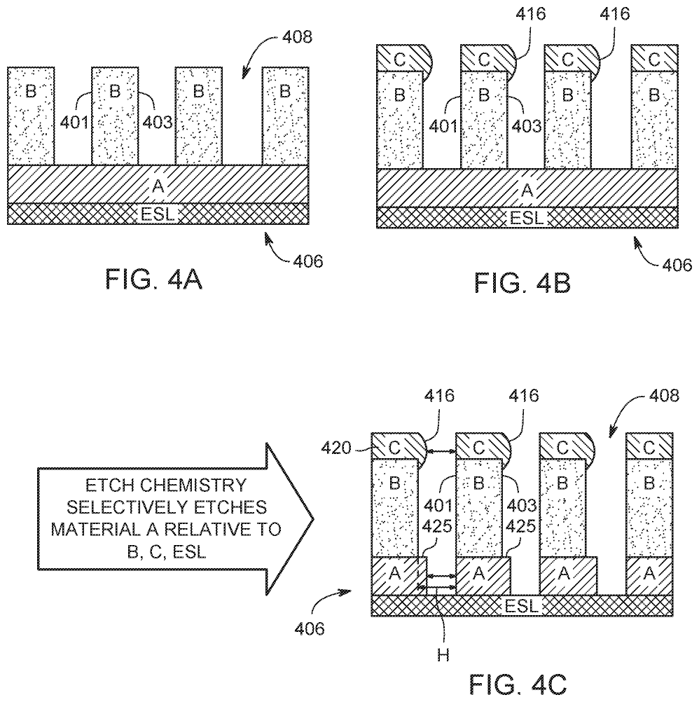

For example, FIGS. 4A-4C illustrate schematic diagrams of a substrate 406 to which PVD and etch processing has been performed, in accordance with at least some embodiments of the disclosure. The substrate 406 is similar to the substrate 306, described above. For example, as depicted in FIG. 4A, the substrate 406 includes a layer A of a first material deposited atop and etch stop layer (ESL) and a layer B of a different material disposed atop the layer A. A plurality of features 408 are formed in the layer B to expose portions of the layer A. The features 408 have opposing sidewalls 401, 403 (e.g., a first sidewall 401 and a second sidewall 403).

An asymmetric PVD process is then performed in the manner as described above to deposit a layer of material 420 atop the layer of material B. As shown in FIG. 4B, an overhang 416 of the material 420 extends beyond the second sidewall 403, but the overhang 416 does not extend beyond the first sidewall 401, which can be achieved, for example, by adjusting one of the previously described parameters, e.g., the substrate support 108 can be rotated about one or more of the x-axis, y-axis, and/or the z-axis, the angle at which the stream of material 420 is provided at, the angle of incidence 130′ that is controlled by the collimator 110, etc.

FIG. 4C depicts the substrate 406 after an etching process has been performed. The portions 425 of the substrate 306 that are covered by the overhang 416 are not etched during the etching process (as described above), which results in the exposed portions of layer A of FIG. 4C being etched less than the layer A of FIG. 4C would have been etched if the substrate 406 did not have the overhang 416 (see area defined by arrow H of FIG. 4C, for example) shading a region of the exposed portion of layer A.

After the substrates 306, 406 have been etched, the material 320, 420 can be removed from the substrates 306, 406 using the target material removal apparatus 40, e.g., dry O₂ ashing or other suitable process for selectively removing the material 320, 420.

In accordance with the disclosure, a critical dimension of the feature etched into layer A of the substrates 306, 406 can be achieved using the methods described herein.

The methods described herein can also be used for creating different etch patterns on a substrate. For example, one or multiple rows of vias can be formed on the substrate.

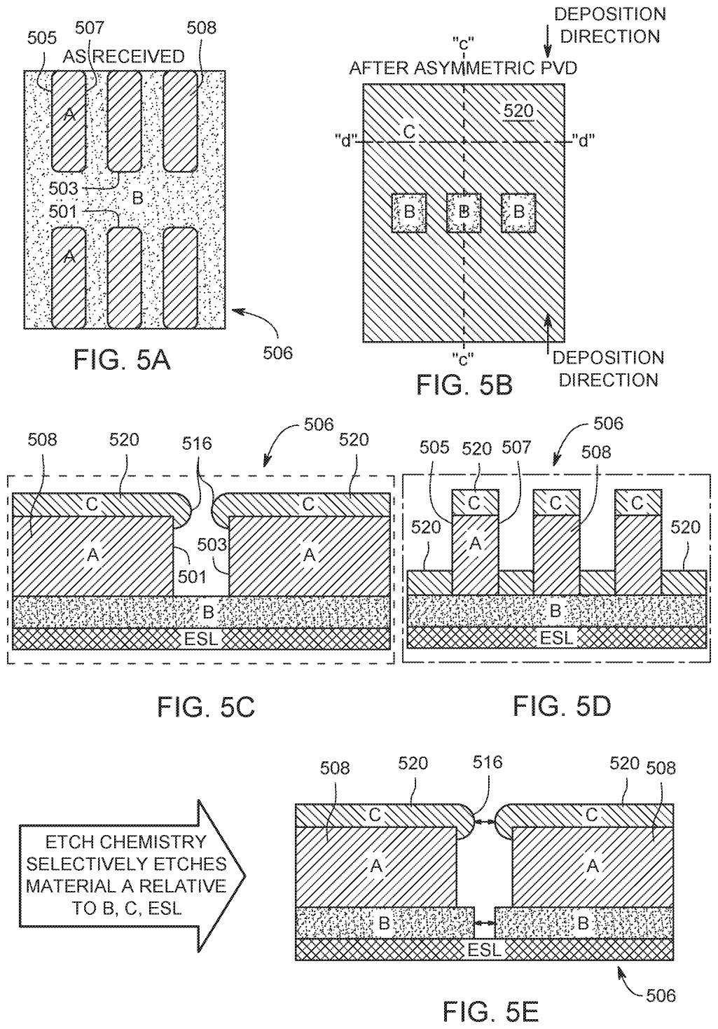

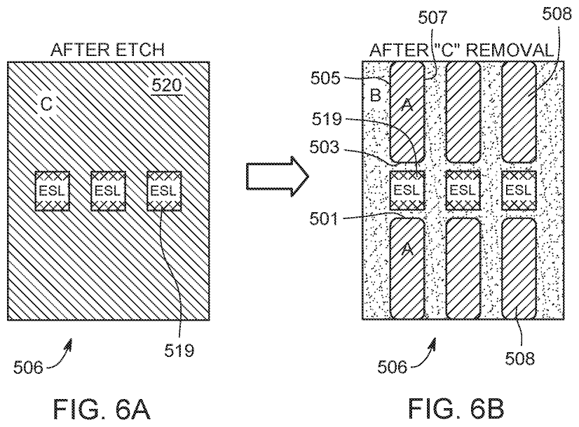

For example, FIGS. 5A-5E illustrate schematic diagrams of a substrate 506 to which PVD and etch processing has been performed, and FIGS. 6A-6B illustrate schematic diagrams of stages of fabrication of a substrate, each in accordance with at least some embodiments of the disclosure.

The substrate 506 and PVD process performed thereon, are similar to the previously described substrates and PVD processes, so only the features that are unique to FIGS. 5A-6B are described herein.

Unlike the previous described substrates, a plurality of individual features 508 extend from a layer B (see FIG. 5A, for example) of the substrate 506, and in addition to an overhang 516 that extends beyond the first and second sidewalls 501, 503 and covers the portion 525 of the layer B (FIGS. 5B and 5C), the material 520 is also deposited between the third and fourth sidewalls 505, 507 of the features 508 (FIG. 5B, and FIG. 6D) to cover the area of layer B between the third and fourth sidewalls 505, 507.

Deposition of the material 520 between the third and fourth sidewalls 505, 507 can be achieved by adjusting, for example, an angle at which the stream of material 520 is deposited toward the substrate 506 and a direction at which the substrate support 108 is moved. For example, after forming the overhang 516 on the features 508, the substrate support 108 can be linearly scanned again, but prior to linearly scanning again, the angle at which the stream of material 520 is directed can be adjusted (e.g., changed to an angle that is different from the a 130, a 132) so that the material 520 is also deposited on the layer B between the third and fourth sidewalls 505, 507.

After the material 520 is deposited, the etching process is performed (FIGS. 5E and 6A) and the material 520 is removed, as described above, thus creating one or more vias 519 through the layer B to the ESL and in between the individual features 508, as shown FIG. 6B.

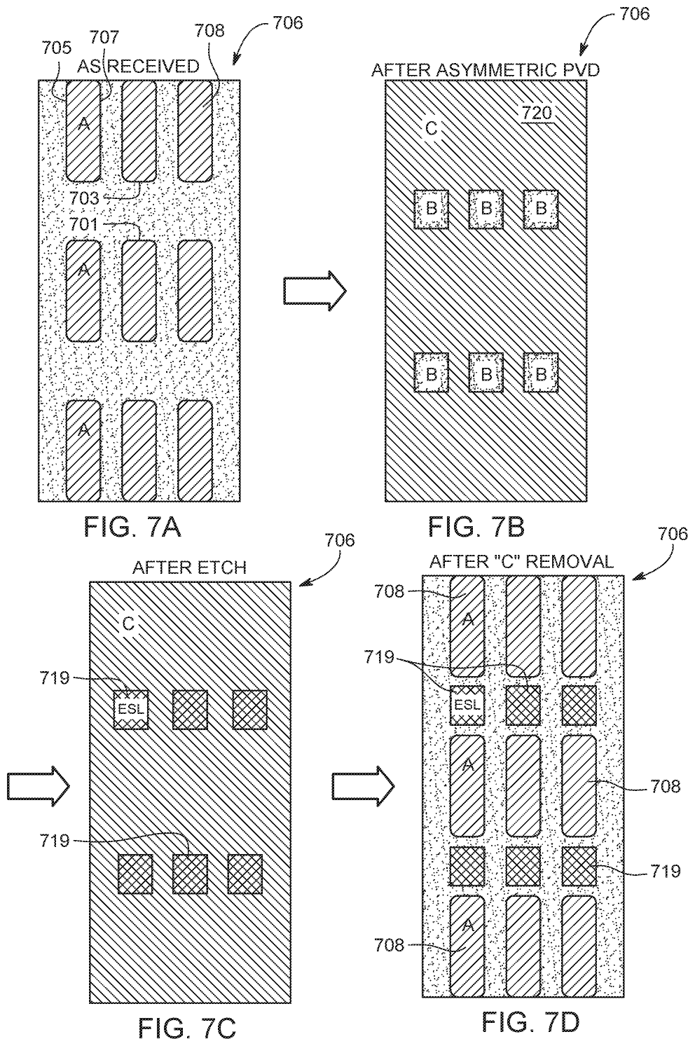

FIGS. 7A-7D illustrate schematic diagrams of processing stages of a substrate (e.g., suitable for DRAM fabrication amongst other applications), in accordance with at least some embodiments of the disclosure. By control of the deposition direction and angle (see FIG. 7B), an overhang (not explicitly shown) extends beyond the first and second sidewalls 701, 703 of the features 708 and the material 720 is deposited on the layer B between the third and fourth sidewalls 705, 707 (FIGS. 7A-7C). As a result, the layer C is deposited atop the features 708 of layer A and atop all of layer B except for openings defined between the features 708. After selective etching, as described above, a plurality of vias 719 are etched into layer B using layer C as a masking layer. As illustrated in FIG. 7D, after selective removal of layer C, multiple rows of vias 719 remain in the layer B between the features 708. The relative size and position of the vias can be controlled by adjusting the one or more parameters described above (e.g., by control of the deposition angle and direction of the stream of material flux relative to the substrate).

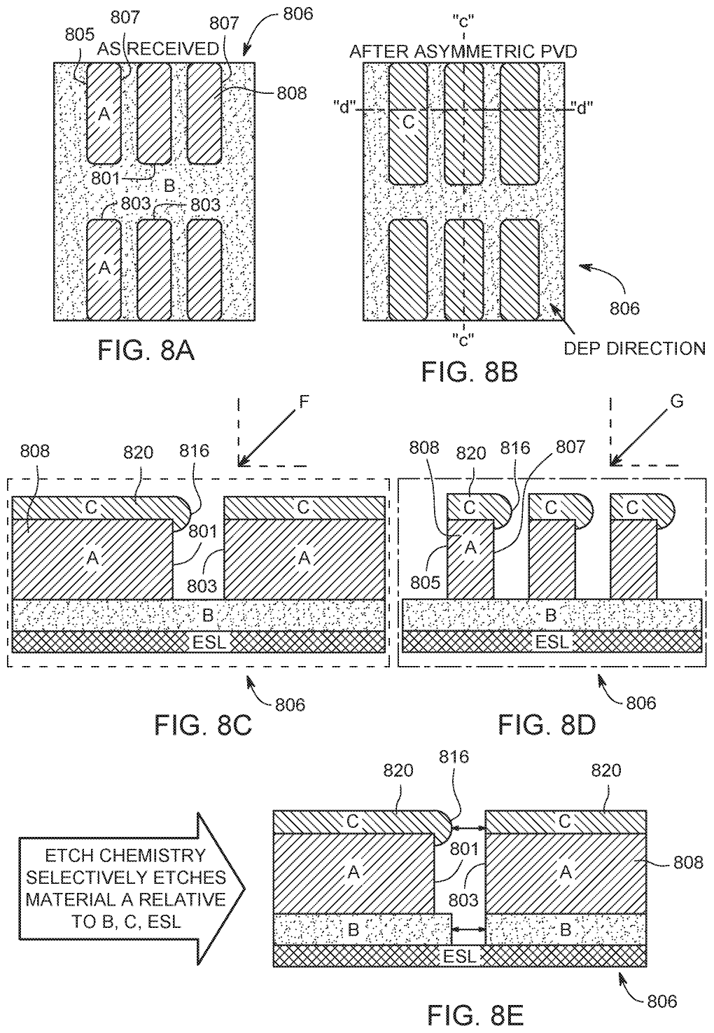

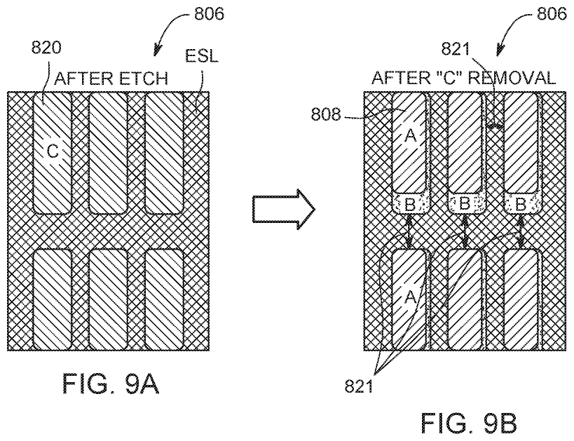

FIGS. 8A-8E illustrate diagrams of a substrate 806 to which PVD and etch processing have been performed, and FIGS. 9A-9B illustrate diagrams of processing stages of the substrate of FIGS. 8A-8E, in accordance with at least some embodiments of the disclosure. The PVD and etch processes described in FIGS. 8A-9B can be used to control a distance, e.g., used for tip-to-tip reduction, between the layers, features, etc., that can be disposed on the substrate 806.

The substrate 806 includes the features 808 (e.g., similar to the features 508 of FIGS. 5A-6B) including first and second sidewalls 801, 803 and third and fourth sidewalls 805, 807 (FIG. 8A). An overhang 816 is formed on the feature 808 to extend beyond the first sidewall 801 (FIGS. 8B and 8C). Additionally, an overhang 816 is formed on the features 808 to extend beyond the fourth sidewall 807 (FIGS. 8B and 8D); little or no overhang is formed on the second sidewall 803 and/or the third sidewall 805. For example, after the substrate support 108 is linearly scanned to form the overhang 816 that extends beyond the first sidewall 801 on the features 808, the substrate support 108 is rotated about 180° relative to and along the same plane as the arrow 116 at which the substrate support 108 was previously scanned and the angle (represented by directional arrow F) at which the stream of material 820 was deposited at to form the overhang 816 extending beyond the first sidewall 801 is changed/adjusted (e.g., about 35° to 45°, represented by directional arrow G) to create on overhang 816 that extends beyond the fourth sidewall 807 (FIG. 8D). A distance that the overhang 816 extends beyond the fourth sidewall 807 can be equal to, less than, or greater than the distance that the overhang 816 extends beyond the first sidewall 801. In FIGS. 8A-9B, the distance that the overhang 816 extends beyond the fourth sidewall 807 is less than the distance that the overhang 816 extends beyond the first sidewall 801.

After the overhangs 816 are formed on the features 808, the etching process is performed on the substrate 806, and the material 820 is removed (FIG. 8E and FIGS. 9A and 9B), both as described above. Unlike the previously described embodiments, however, the overhangs 816 that extend beyond the first and fourth sidewalls 801 and 807 allow for removal of a majority of the layer B which allows for tip-to-tip reduction of the substrate 806, as indicated by arrows 821 (FIG. 9B), which shows the remaining portions of the substrate 806 relative to the feature 808 after the etching process.

The methods and apparatus described herein can advantageously be used for critical dimension reduction of a substrate, for reducing a distance between one or more of the various components that can be disposed on a substrate, and for creating various patterns on a substrate, in a more efficient manner than conventional methods and apparatuses that are configured to perform similar operations during substrate fabrication.

While the foregoing is directed to embodiments of the present disclosure, other and further embodiments of the disclosure may be devised without departing from the basic scope thereof.

What is claimed is:

1. A method for processing a substrate, comprising:
directing a stream of material from a PVD source toward a surface of a substrate at a non-perpendicular angle to the plane of the surface to selectively deposit the material on a top portion of one or more features on the substrate and form an overhang extending beyond a first sidewall of the one or more features; and
etching a first layer of the substrate beneath the one or more features selective to the deposited material.

2. The method of claim 1, further comprising:
prior to etching the first layer, rotating the substrate;
directing the stream of material from the PVD source toward the surface of the substrate at the non-perpendicular angle to the plane of the surface to selectively deposit the material on the top portion of the one or more features on the substrate and form an overhang extending beyond a second sidewall, opposite the first sidewall, of the one or more features; and
etching the first layer of the substrate beneath the one or more features selective to the deposited material.

3. The method of claim 2, wherein the substrate is rotated 180°.

4. The method of claim 1, further comprising:
prior to etching the first layer, rotating the substrate;
directing the stream of material from the PVD source toward the surface of the substrate at the non-perpendicular angle to the plane of the surface to selectively deposit the material on the top portion of the one or more features on the substrate and form an overhang extending beyond a third sidewall, adjacent the first sidewall, of the one or more features; and
etching the first layer of the substrate beneath the one or more features selective to the deposited material.

5. The method of claim 4, wherein the substrate is rotated 90°.

6. The method of claim 1, further comprising:
prior to etching the first layer, rotating the substrate;
directing the stream of material from the PVD source toward the surface of the substrate at a different non-perpendicular angle to the plane of the surface to selectively deposit the material on the top portion of the one or more features on the substrate and form an overhang extending beyond a second sidewall, opposite the first sidewall, of the one or more features; and
etching the first layer of the substrate beneath the one or more features selective to the deposited material.

7. The method of claim 6, wherein a distance that overhang extends beyond the first sidewall is at least one of greater than or less than a distance that the overhang extends beyond the second sidewall.

8. The method of claim 1, further comprising:
prior to etching the first layer, rotating the substrate;
directing the stream of material from the PVD source toward the surface of the substrate at a different non-perpendicular angle to the plane of the surface to selectively deposit the material on the top portion of the one or more features on the substrate and form an overhang extending beyond a third sidewall, adjacent the first sidewall, of the one or more features; and
etching the first layer of the substrate beneath the one or more features selective to the deposited material.

9. The method of claim 8, wherein a distance that the overhang extends beyond the first sidewall is at least one of greater than or less than a distance that the overhang extends beyond the third sidewall.

10. The method of claim 1, further comprising removing the material deposited via the PVD source from the substrate.

11. A method for processing a substrate, comprising:
directing a stream of material from a PVD source toward a surface of a substrate at a non-perpendicular angle to the plane of the surface to selectively deposit the material on a top portion of one or more features on the substrate and form an overhang extending beyond a first sidewall of the one or more features;
rotating the substrate;
directing a stream of material from the PVD source toward a surface of a substrate at a different non-perpendicular angle to the plane of the surface to selectively deposit the material on the top portion of the one or more features on the substrate and form an overhang extending beyond at least one of a second sidewall and a third sidewall of the one or more features; and
etching a first layer of the substrate beneath the one or more features selective to the deposited material.

12. The method of claim 11, wherein the material is at least one of titanium (Ti) nitride (TiN), silicon (Si), silicon nitride (SiN), and silicon oxynitride (SiON).

13. The method of claim 11, wherein a distance that the overhang extends beyond the first sidewall and beyond at least one of the second sidewall and third sidewall is varied for at least one of:
a) controlling critical dimension reduction on the substrate;
b) forming at least one pattern on the substrate; and
c) controlling tip-to-tip reduction on the substrate.

14. The method of claim 13, wherein the at least one pattern formed on the substrate comprises a plurality of vias.

15. A nontransitory computer readable storage medium having stored thereon a plurality of instructions that when executed cause a process controller to perform a method for processing a substrate, the method comprising:
directing a stream of material from a PVD source toward a surface of a substrate at a non-perpendicular angle to the plane of the surface to selectively deposit the material on a top portion of one or more features on the substrate and form an overhang extending beyond a first sidewall of the one or more features; and
etching a first layer of the substrate beneath the one or more features selective to the deposited material.

16. The nontransitory computer readable storage medium of claim 15, further comprising:
prior to etching the first layer, rotating the substrate 180°, directing the stream of material from the PVD source toward the surface of the substrate at the non-perpendicular angle to the plane of the surface to selectively deposit the material on the top portion of the one or more features on the substrate and form an overhang extending beyond a second sidewall, opposite the first sidewall, of the one or more features; and
etching the first layer of the substrate beneath the one or more features selective to the deposited material.

17. The nontransitory computer readable storage medium of claim 15, further comprising:
prior to etching the first layer, rotating the substrate 90°;
directing the stream of material from the PVD source toward the surface of the substrate at the non-perpendicular angle to the plane of the surface to selectively deposit the material on the top portion of the one or more features on the substrate and form an overhang extending beyond a third sidewall, adjacent the first sidewall, of the one or more features; and
etching the first layer of the substrate beneath the one or more features selective to the deposited material.

18. The nontransitory computer readable storage medium of claim 15, further comprising:
prior to etching the first layer, rotating the substrate;
directing the stream of material from the PVD source toward the surface of the substrate at a different non-perpendicular angle to the plane of the surface to selectively deposit the material on the top portion of the one or more features on the substrate and form an overhang extending beyond a second sidewall, opposite the first sidewall, of the one or more features; and
etching the first layer of the substrate beneath the one or more features selective to the deposited material,
wherein a distance that overhang extends beyond the first sidewall is at least one of greater than or less than a distance that the overhang extends beyond the second sidewall.

19. The nontransitory computer readable storage medium of claim 15, further comprising:
prior to etching the first layer, rotating the substrate;
directing the stream of material from the PVD source toward the surface of the substrate at a different non-perpendicular angle to the plane of the surface to selectively deposit the material on the top portion of the one or more features on the substrate and form an overhang extending beyond a third sidewall, adjacent the first sidewall, of the one or more features; and
etching the first layer of the substrate beneath the one or more features selective to the deposited material,
wherein a distance that the overhang extends beyond the first sidewall is at least one of greater than or less than a distance that the overhang extends beyond the third sidewall.

20. The nontransitory computer readable storage medium of claim 15, further comprising: removing the material deposited via the PVD source from the substrate.
